(19) United States
(12) Patent Application Publication
(10) Pub. No.: US 2019/0043963 A1
(43) Pub. Date: Feb. 7, 2019

(54) TRANSISTOR ELEMENT WITH GATE ELECTRODE OF REDUCED HEIGHT AND RAISED DRAIN AND SOURCE REGIONS AND METHOD OF FABRICATING THE SAME

(71) Applicant: GLOBALFOUNDRIES Inc., Grand Cayman (KY)

(72) Inventors: Peter Baars, Dresden (DE); Hans-Juergen Thees, Dresden (DE); Clemens Fitz, Dresden (DE)

(21) Appl. No.: 15/667,755

(22) Filed: Aug. 3, 2017

(51) Int. Cl. H01L 29/66; H01L 29/417

(52) U.S. Cl. CPC H01L 29/66575; H01L 29/41783

(57) ABSTRACT

A transistor element of a sophisticated semiconductor device includes a gate electrode structure including a metal-containing electrode material instead of the conventionally used highly doped semiconductor material. The metal-containing electrode material may be formed in an early manufacturing stage, thereby reducing overall complexity of patterning the gate electrode structure in approaches in which the gate electrode structure is formed prior to the formation of the drain and source regions. Due to the metal-containing electrode material, high conductivity at reduced parasitic capacitance may be achieved, thereby rendering the techniques of the present disclosure as highly suitable for further device scaling.

### BACKGROUND

### 1. Field of the Disclosure

Generally, the present disclosure relates to transistor elements of semiconductor devices and respective manufacturing techniques, and, more particularly, to a transistor element with a gate electrode of reduced height and raised drain and source regions and a method of fabricating the same.

### 2. Description of the Related Art

Significant progress has been made in the field of semiconductor devices, when considering overall integration density, power consumption, switching speed and the like. Sophisticated integrated circuits up to and beyond several millions of field effect transistors may be typically implemented in complex control circuitry, thereby providing the potential of integrating increasingly additional functions into a single semiconductor chip. In recent developments, even entire electronic systems have been integrated into a single chip, wherein, in particular, frequently, radio frequency (RF) circuit portions may have to be incorporated into the overall circuit design, for instance, for providing wireless communication capabilities and the like.

Generally, a field effect transistor typically used in complex CMOS techniques comprises a channel region in which a conductive channel may form upon the application of an appropriate control voltage applied to a gate electrode structure, which is typically formed from a gate dielectric material positioned in contact with the channel region and an electrode material, frequently provided in the form of a highly doped semiconductor material, in order to appropriately control the formation of the conductive channel. Consequently, when additionally applying an operating voltage between the source region and the drain region of the field effect transistor, the conductivity of the channel region may be controlled on the basis of the control voltage applied to the gate electrode, wherein respective transistor characteristics may be determined by, for instance, transistor geometry, material composition and the like. For example, in digital control circuitry, the field effect transistors are typically operated in a digital or switched mode, in which the transistor element is switched between a highly conductive state and a high ohmic (resistive) state. Thus, for high performance of any such transistors, it may be desirable to provide the highly conductive state with very low ohmic resistance, while the high ohmic state should exhibit high resistance so as to reduce undesired static leakage currents, which may otherwise contribute to overall power consumption. Therefore, conventionally, the respective drain and source regions in combination with the channel region have been appropriately doped with specific dopant species in order to form a PN junction and to provide the desired electronic characteristics. Moreover, the gate electrode structure may be appropriately configured so as to provide a high capacitive coupling from the gate electrode material into the channel region in order to achieve efficient channel controllability and, thus, switching characteristics of the respective field effect transistor.

Over many years, the characteristics of such field effect transistors and entire integrated circuits, including a plurality of such transistor elements, has been improved by continuously reducing the transistor dimensions, wherein, in particular, the gate length represents a critical device parameter that significantly affects the transistor characteristics. Basically, upon reducing the gate length of a field effect transistor, its switching speed may be typically increased in addition to an increase of integration density due to the reduced overall lateral dimension of the field effect transistors. At the same time, there is an ongoing tendency to reduce the supply voltage and, thus, the operating voltages of a transistor element, so as to decrease overall power consumption, for instance, by reducing respective leakage currents, which may be particularly induced into and through the gate dielectric material, since a reduction of gate length is usually accompanied by a reduction of the thickness of the gate dielectric material in order to provide a desired minimum capacitive coupling between the gate electrode and the channel region. Since the supply voltage may not be reduced to extremely low values, a further reduction of the thickness of the gate dielectric material, when composed of standard dielectric materials, such as silicon dioxide, silicon nitride and the like, may become increasingly problematic due to the over-proportional increase of respective leakage currents.

For this reason, significant efforts have been made in order to provide a much reduced oxide equivalent thickness, however, at a desired physical thickness sufficient to maintain leakage currents at an acceptable level. Hence, complex material systems on the basis of socalled “high-k” dielectric materials, i.e., dielectric materials having a dielectric constant of 20 or even higher, have been incorporated, thereby insuring a physical thickness of several nanometers, while still providing high capacitive coupling on the basis of an oxide equivalent thickness that is approximately 2 nm and significantly less.

Although high capacitive coupling between the gate electrode and the channel region is basically a necessity for the required channel controllability, in particular, for ever-decreasing channel lengths, other capacitances involved in a field effect transistor are typically considered as parasitic capacitances, since these mostly undesirable capacitances may negatively affect the switching speed of respective transistor elements. For example, the drain/gate and the source/gate capacitance may contribute to a reduced switching speed and, thus, to significant dynamic losses, particularly when operating the respective field effect transistors on the basis of moderately high clock frequencies. Consequently, in recent years, a plurality of different approaches have been taken and investigated in order to further reduce overall transistor dimensions and to further increase performance, while maintaining power consumption at an acceptable level. In some approaches, the problem of less pronounced channel control and transistor performance has been addressed by implementing three-dimensional transistor architectures, in which a fin of semiconductor material is at least on two sidewall surface areas positioned adjacent to a respective gate electrode structure, thereby increasing capacitive coupling and current-carrying capacity of the transistor element. On the other hand, significant additional process steps may be required for implementation of the three-dimensional configuration, thereby significantly adding to the overall production costs of such sophisticated semiconductor devices.

In other very promising approaches, the well-established planar transistor configuration may be preserved and required capacitive coupling between the gate electrode structure and the channel region may be insured by using sophisticated high-k dielectric materials in combination with appropriate work function-adjusting metal-containing materials, as discussed above, while at the same time a fully depleted channel region may be established with little or no dopant concentration in order to enhance charge carrier speed and reduce overall parasitic capacitance of the respective transistor body. In this manner, gate lengths of 30 nm and significantly less have been introduced into the fabrication regime of planar transistors with fully depleted semiconductor layers having formed therein the channel regions. In further sophisticated applications, the fully depleted planar transistor configuration is established on the basis of a silicon-on-insulator (or semiconductor-on-insulator) (SOI) configuration, wherein the fully depleted configuration of the channel-containing semiconductor layer may be established on the basis of a very thin semiconductor layer having a thickness of 15 nm and significantly less, which is formed on a buried insulating layer. Although a fully depleted transistor configuration based on a very thin active semiconductor layer for the channel region may also be implemented on the basis of a bulk configuration, the SOI architecture provides several additional advantages, such as reduced parasitic capacitance of the respective active semiconductor material, an efficient mechanism for adjusting transistor characteristics, such as threshold voltage and the like, providing an additional mechanism for adjusting channel controllability, and the like.

Although the concept of using planar transistors with fully depleted configuration may provide significant advantages in terms of overall production costs compared to sophisticated three-dimensional transistor architectures, it turns out, however, that further device scaling may require further consideration of parasitic capacitances and other process-related issues, such as the appropriate positioning of respective contact elements connecting to the drain and source regions and the gate electrode structure, in order to avoid undue reduction of overall production yield.

For example, a typical sophisticated planar transistor element may be formed in accordance with the following well-established process techniques. Depending on whether a bulk configuration or an SOI configuration is to be employed as the basic transistor architecture, a thin silicon layer may be epitaxially grown on a corresponding semiconductor substrate, such as a silicon substrate, and this thin semiconductor material may be prepared with respect to dopant concentration, material composition and the like, as required for forming therein and thereon respective transistor elements. For an SOI architecture, a corresponding substrate may be provided in which a thin semiconductor material, such as a silicon material, may be formed on a buried insulating layer, wherein the semiconductor material may have a thickness of 15 nm and less. After forming respective isolation structures, such as shallow trench isolations and the like, which may at least laterally delineate the respective thin active semiconductor material, a gate electrode structure may be formed by initially forming a basis dielectric material by deposition and/or oxidation with very reduced thickness, followed by the deposition of the “actual” gate dielectric material, which may have to provide the required physical thickness without unduly increasing the “electrical” thickness or oxide equivalent thickness. To this end, a plurality of well-established material systems are well known in the art, such as high-k dielectric materials based on hafnium oxide and the like. To this end, well-established deposition techniques may be applied, followed by a respective deposition of a material system, including respective metal species, such as titanium, aluminum and the like, which are appropriately patterned so as to adjust respective work functions for N-type transistors and P-type transistors, respectively.

For example, a layer stack of titanium nitride, aluminum and the like may be typically provided so as to obtain the desired adjustment of the work function and to also provide reduced electrical resistance of the gate electrode material positioned in the immediate vicinity of the gate dielectric material. It should be appreciated that highly doped semiconductor material, such as highly doped polysilicon material, may no longer suffice for obtaining a desired electrostatic influence on the channel region, and must be replaced, at least in the vicinity of the high-k dielectric material, by these sophisticated material systems.

Thereafter, the main portion of the gate electrode material may be formed, for instance, by depositing a substantially amorphous silicon layer, introducing a desired dopant species with high concentration and performing an anneal process for substantially recrystallizing the amorphous highly doped silicon material. Since respective gate electrode structures have to be formed on the basis of a gate length of 30 nm and significantly less, such as 22 nm, 12 nm and the like, the overall conductivity of the gate electrode material, i.e., substantially of the recrystallized highly doped silicon material, may be determined by the cross-sectional area of the gate line, so that a specific gate height is necessary for obtaining the desired low line resistance of the gate electrode structures.

Thereafter, a cap material, such as silicon nitride, possibly in combination with silicon dioxide, may be deposited and may be patterned on the basis of highly sophisticated lithography techniques in order to form a mask on the previously formed gate layer stack in conformity with the required gate length. To this end, the lithography process is followed by appropriate anisotropic etch techniques for appropriately patterning the dielectric cap material. On the basis of the cap material, the actual gate patterning process may be performed, for instance, by initially etching through the highly doped silicon material, which may require respective anisotropic etch recipes. Thereafter, sophisticated yet well-established etch techniques may be applied so as to etch through the metal-containing electrode materials, finally removing exposed portions of the gate dielectric material. In this manufacturing stage, the gate electrode structures, including the high-k dielectric material, the metal-containing work function, barrier materials and the actual electrode materials, are provided with the desired gate length, while the structure is still covered by the respective cap material.

Next, a respective masking regime may be applied, for instance, by depositing a spacer material, such as silicon nitride and the like, and removing the spacer material from one type of transistor, thereby also exposing the semiconductor areas adjacent to the respective gate electrode structure, which may represent the areas in and on which the drain and source regions are to be formed. After respective cleaning sequences for preparing the exposed semiconductor surface areas, a selective epitaxial growth process may be applied, in which a desired material composition and, in particular, a dopant concentration, may also be established by appropriately providing a gaseous ambient, including the required species. Consequently, the respective drain and source regions, also referred to as raised drain and source regions, may be formed immediately adjacent to the gate electrode structure, separated from the sensitive gate materials by the previously formed sidewall spacer, wherein the raised drain and source regions may extend along a significant part of the height of the gate electrode structure. Similarly, after appropriately masking the transistor having the previously formed raised drain and source regions, sidewall spacers may be formed in the other type of transistor element, followed by respective cleaning processes and a selective epitaxial growth process, in which the appropriate dopant species and material composition for the raised drain and source regions of the other type of transistor elements may be formed.

Thereafter, respective mask materials may have to be removed. Subsequently, the mask material on the gate electrode structure may be removed by sophisticated, yet well-established, etch recipes, including wet chemical and/or plasma-assisted etch processes, thereby finally exposing the highly-doped semiconductor material, such as the silicon material, of the gate electrode structure. As a side effect of the corresponding cap material removal, a certain amount of the previously grown semiconductor material may also be removed.

Thereafter, a process sequence may be applied in which exposed semiconductor surface areas may be cleaned and prepared for forming a respective semiconductor metal compound therein, such as a nickel silicide composition, requiring the deposition of a nickel, possibly in combination with a certain amount of platinum, followed by anneal processes and an intermittent removal of any excess metal material. In this manner, in particular, the contact resistance of the drain and sources regions and the gate electrode structures may be reduced when forming respective contact elements so as to connect to the drain and source regions and to the gate electrode structure. That is, after forming one or more dielectric materials above the respective transistor elements, respective contact openings may be formed by sophisticated lithography and etch techniques, so as to simultaneously expose respective contact areas in the drain and source regions and the gate electrode structures. Typically, a respective patterning sequence may be performed concurrently for these contact openings, since these contact openings extend substantially to a similar height or depth, since the raised drain and source regions and the gate electrode structures are of comparable height. In particular, upon further reducing the critical dimensions of the transistor elements, the patterning sequence for forming the contact openings, in particular, the contact openings for the drain and source regions, becomes increasingly challenging since respective overlay errors may result in undesired shorting of the drain and/or source region with the gate electrode structure when a respective contact opening exposes, due to an overlay error, not only a part of the drain or source region, but also a part of the adjacent gate electrode material. Consequently, the formation of the contact elements for connecting to the drain and source regions may result in significant yield loss.

Moreover, it turns out that overall resistance of the gate electrode structures formed in accordance with the process techniques described above, as well as the resulting parasitic capacitance between the gate electrode structure and the raised drain and source regions, may have a significant negative influence on the transistor performance, in particular, on further reduced transistor length dimensions.

For addressing some of the above-identified problems, sophisticated manufacturing techniques have been developed in which the gate electrode structures may be formed in a very late manufacturing stage by replacing a dummy gate electrode structure, thereby, however, contributing to overall increased process complexity and rendering these approaches less than desirable for many sophisticated semiconductor products.

In view of the situation described above, the present disclosure, therefore, relates to techniques in which field effect transistors may be formed on the basis of a planar configuration with high compatibility to process techniques described above, while avoiding, or at least reducing, the effects of one or more of the problems identified above.

### SUMMARY OF THE DISCLOSURE

The following presents a simplified summary of the disclosure in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure is based on the concept that a plurality of advantages may be gained by reducing the height of respective complex gate electrode structures by forming a highly conductive metal-containing electrode material in an early manufacturing stage. In this manner, overall conductivity of the gate electrode structures may be preserved at a required level, even for further reduced gate length dimensions, while, at the same time, the parasitic capacitance between the gate electrode structure and adjacent drain and source regions, for example, raised drain and source regions, may be maintained at a low level. In some illustrative embodiments disclosed herein, the early formation of a highly conductive electrode material for the gate electrode structures may not only provide a high degree of compatibility with well-established process techniques, but may even enable a reduced overall complexity, since some sophisticated and critical processes may be omitted, such as, in some cases, the formation of a metal semiconductor compound in the drain and source regions, which is typically associated with a number of related process steps. Moreover, by providing the gate electrode structure with reduced height, in some illustrative embodiments disclosed herein, the problem of overlay errors and margins upon forming contact openings extending to the raised drain and source regions may be significantly relaxed, since the surface of the electrode material of the gate electrode structure may be typically positioned at a lower height level compared to the surface of the raised drain and source regions.

According to one illustrative embodiment disclosed herein, a method includes forming a metal-containing layer as a top electrode material of a gate electrode structure of a transistor element. Furthermore, the method includes, after the formation of the top electrode material, forming raised drain and source regions of the transistor element.

According to a further illustrative embodiment disclosed herein, a method of forming a transistor element is provided. The method includes forming one or more metal-containing material layers above a gate dielectric layer, wherein the one or more metal-containing material layers form an electrode material of a gate electrode structure and extend to a first height. The method further includes forming drain and source regions so as to extend to a second height, wherein the first height is less than the second height.

In a still further illustrative embodiment disclosed herein, a transistor element is provided. The transistor element includes a gate electrode structure including a gate dielectric material and one or more metal-containing material layers, wherein a surface of an uppermost layer of the one or more metal-containing material layers is positioned at a first height. The transistor element further includes drain and source regions that extend to a second height that is greater than the first height.

### BRIEF DESCRIPTION OF THE DRAWINGS

The disclosure may be understood by reference to the following description taken in conjunction with the accompanying drawings, in which like reference numerals identify like elements, and in which:

FIG. 1 schematically illustrates a cross-sectional view of a semiconductor device, including a transistor element, in an early manufacturing stage in which sophisticated gate dielectric materials are formed on a semiconductor material;

FIG. 2 schematically illustrates a cross-sectional view of the semiconductor device after deposition of a material system of a gate electrode in order to adjust work function and other characteristics of sophisticated gate electrode structures;

FIG. 3 schematically illustrates a cross-sectional view of the semiconductor device in a further advanced manufacturing stage, in which a metal-containing electrode material is formed above a previously formed material system;

FIG. 4 schematically illustrates a cross-sectional view of the semiconductor device having a dielectric cap material that is patterned so as to act as a patterning mask for structuring the underlying gate layer stack;

FIG. 5 schematically illustrates a cross-sectional view of a sophisticated gate electrode structure in a patterned state;

FIG. 6 schematically illustrates the semiconductor device in a further advanced manufacturing stage, in which raised drain and source regions are formed adjacent to the gate electrode structure;

FIG. 7 schematically illustrates a cross-sectional view of the semiconductor device according to additional embodiments of the present disclosure, in which a semiconductor metal compound may be formed in the raised drain and source regions;

FIG. 8A schematically illustrates a cross-sectional view of the semiconductor device according to other illustrative embodiments, wherein contact openings may be formed to extend to the drain and source regions separately with respect to a contact opening extending to the gate electrode structure;

FIG. 8B schematically illustrates the semiconductor device according to further illustrative embodiments, in which contact openings extending to the raised drain and source regions and to the gate electrode structure maybe formed in a common patterning sequence;

FIG. 9 schematically illustrates the semiconductor device in a further advanced manufacturing stage according to the optional embodiments in accordance with the embodiments illustrated in FIG. 7, wherein contact openings may be formed so as to extend to the semiconductor metal compounds formed in the drain and source regions, wherein the contact opening extending to the gate electrode structure may be formed concurrently or separately with respect to the contact openings for the drain and source regions; and

FIG. 10 schematically illustrates the semiconductor device in a further advanced manufacturing stage in accordance with embodiments in which contact resistance in the raised drain and source regions may be reduced on the basis of a metal semiconductor compound formed therein on the basis of the respective contact openings.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

In the following description, for the purposes of explanation, numerous specific details are set forth in order to provide a thorough understanding of exemplary embodiments. It should be apparent, however, that exemplary embodiments may be practiced without these specific details or with an equivalent arrangement. In other instances, well-known structures and devices are shown in block diagram form in order to avoid unnecessarily obscuring exemplary embodiments. In addition, unless otherwise indicated, all numbers expressing quantities, ratios and numerical properties of ingredients, reaction conditions and so forth used in the specification and claims are to be understood as being modified in all instances by the term “about.”

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present disclosure contemplates the formation of a highly conductive gate electrode material in the form of a metal, such as tungsten, nickel and the like, in an early manufacturing stage, thereby providing the potential for reducing the overall height of the gate electrode structure, even if further reduced transistor length dimensions have to be implemented. By incorporating the highly conductive metal-based gate electrode material in an early manufacturing stage, not only a high degree of compatibility with existing process techniques for forming sophisticated transistor elements may be preserved, but even a significant reduction in overall complexity may be achieved, at least in some illustrative embodiments, since some critical process steps may be omitted. Moreover, the reduced height level of the gate electrode structure compared to the height level of the raised drain and source regions may not only result in reduced parasitic capacitance, but may, in some illustrative embodiments, contribute to superior process robustness, since overlay error margins may be significantly relaxed for forming the contacts connecting to the raised drain and source regions, since the laterally adjacent gate electrode material is at a lower height level, thereby reducing the risk of creating short circuits or non-reliable contact elements during the formation of the contact elements. Consequently, the present disclosure provides the potential for further device scaling, while additionally reducing overall process complexity and, thus, cost, while at the same time, performance of transistor elements may be enhanced, which may be highly advantageous for complex systems, including RF applications and the like.

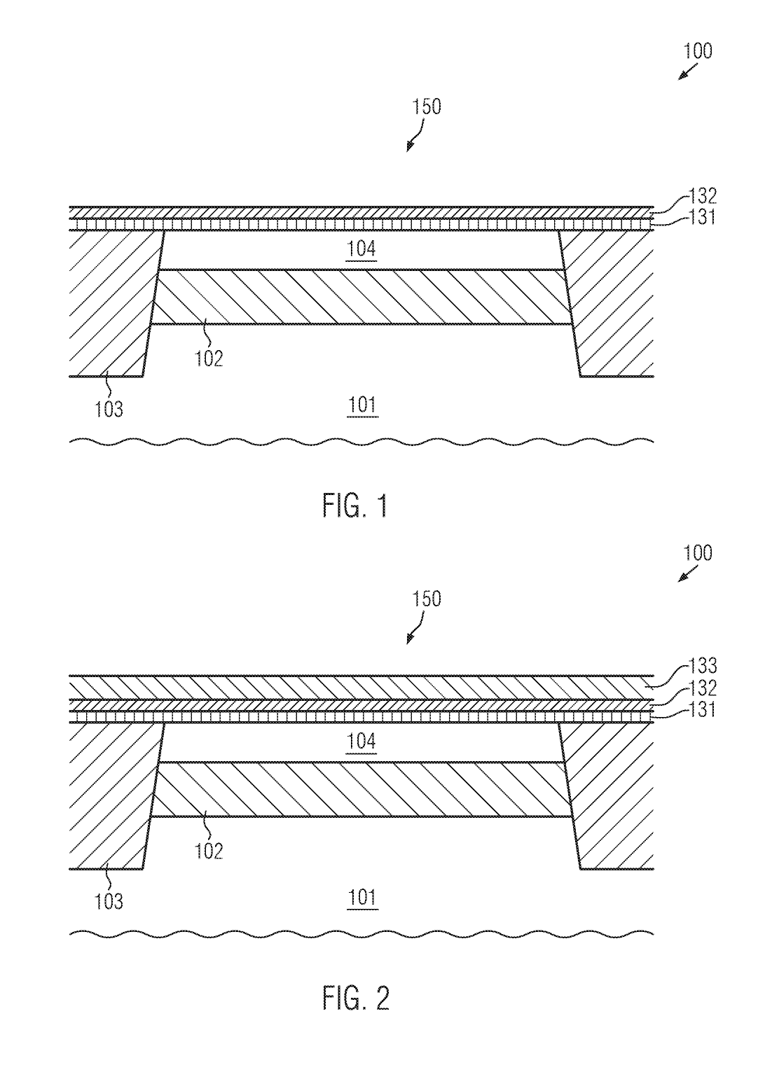

FIG. 1 schematically illustrates a cross-sectional view of a semiconductor device 100 in an early manufacturing stage. The semiconductor device 100 may comprise or receive a plurality of transistor elements, wherein, for convenience, a single transistor element 150 may be referred to, wherein it is to be appreciated that, typically, a plurality of transistor elements of different type, such as P-type transistor elements, N-type transistor elements, transistor elements to be operated on the basis of elevated supply voltages, storage transistor elements and the like, may be provided in complex semiconductor devices, including very different functional portions, as already discussed above. The transistor element 150 still to be formed may represent, in some illustrative embodiments, a small signal or low power transistor element that may be used for digital control circuitry, RF small signal circuit portions and the like, and may represent an N-type transistor or a P-type transistor, wherein it should be appreciated that, typically, both types of transistors may be formed during a common manufacturing sequence in sophisticated CMOS approaches.

In the embodiment shown in FIG. 1, the transistor 150 still to be formed may represent an SOI architecture in which an “active” semiconductor layer 104 is formed on a buried insulating layer 102, which, in turn, is formed on a typically crystalline semiconductor material 101, such as silicon. It should be appreciated that, in other cases, the active semiconductor layer 104 may be provided in the form of a “bulk” architecture, in which the semiconductor layer 104 may represent an upper portion of the crystalline substrate material 101, while, in still other cases, both device architectures may typically be present within the same semiconductor device. For example, in a region laterally adjacent to the active semiconductor layer 104, a semiconductor region may be formed so as to directly connect to the substrate material 101 in order to provide contact thereto, thereby enabling the implementation of superior control mechanisms, such as adjustment of threshold voltage, influencing channel controllability of a channel region to be formed in the semiconductor layer 104, and the like. For convenience, any such “hybrid” configuration is not shown in FIG. 1. Thus, it should be appreciated that, although the SOI architecture shown in FIG. 1 may have significant advantages with respect to overall transistor performance, as already discussed above, the principles of the present disclosure may not be restricted to SOI architectures and may, instead, also be applied to other sophisticated planar transistor geometries.

In the manufacturing stage shown in FIG. 1, the semiconductor device 100 may further comprise an isolation structure 103, such as a shallow trench isolation, which may include appropriate dielectric materials, such as silicon dioxide, silicon nitride and the like, and which may extend at least through the semiconductor layer 104 so as to provide a lateral boundary of a respective transistor active region. In the embodiment shown, the isolation structure 103 may also extend through the buried insulating layer 102 and may extend into the substrate material 101. It should be appreciated that other isolation structures (not shown) having an increased penetration depth compared to the isolation structure 103 may be provided at various device regions, for instance, for laterally delineating “hybrid” areas, as discussed above, in accordance with overall device requirements.

Furthermore, as also discussed above, in some illustrative embodiments, the transistor element 150 may be formed on the basis of a fully depleted configuration, which may be typically accomplished by providing the active semiconductor layer 104 with an appropriate initial thickness of, for instance, 15 nm and less, and the buried insulating layer 102 may also be provided with appropriate thickness and material composition so as to provide efficient additional control mechanisms, as discussed above. For instance, the buried insulating layer 102 may be formed of silicon dioxide with a thickness of 20 nm or more, while, in other cases, the buried insulating layer 102 may include two or more different materials so as to specifically engineer the characteristics thereof in view of the overall device requirements.

It should also be appreciated that the semiconductor layer 104 may be different in thickness and/or material composition depending on the type of transistor to be formed. For example, typically, a silicon/germanium mixture may be provided, at least in a significant portion of the semiconductor layer 104, when a P-type transistor is to be formed, while a silicon or silicon/carbon mixture may be provided for N-type transistors. It should be appreciated, however, that any other material composition may be selected in accordance with overall device requirements. Furthermore, in the manufacturing stage shown, the semiconductor layer 104 may have included therein a respective dopant concentration which may be moderately low, while, in other cases, a substantially intrinsic semiconductor material may be used. Similarly, the substrate material 101 may include any doped semiconductor regions (not shown) as may be required for forming and operating the transistor element 150. For example, an appropriate dopant concentration may be established below the semiconductor layer 104 within the substrate material 101, thereby providing an efficient mechanism for fine-tuning a threshold voltage of a channel region still to be formed in the semiconductor layer 104.

Furthermore, in the manufacturing stage shown, an appropriate gate dielectric material, for instance, in the form of a first basis material 131, such as silicon dioxide, silicon nitride, silicon oxynitride and the like, may be provided, with a thickness in conformity with overall device requirements. For instance, the layer 131 may have a thickness of 2 nm and even significantly less, such as 1 nm and less, as typically required in sophisticated transistor elements. Furthermore, the gate dielectric material may include a further material layer 132, which may represent a high-k dielectric material having a dielectric constant of 20 and significantly higher, wherein amorphous oxides of metals, such as aluminum oxide, tantalum oxide and the like, amorphous oxides of transition metals, such as hafnium oxide, zirconium oxide, and mixed oxides in the form of hafnium silicate, zirconium silicate, and the like, may be frequently used.

The semiconductor device 100 as shown in FIG. 1 may be formed on the basis of the following processes. The substrate 101 may be provided so as to include the buried insulating layer 102 and an initial semiconductor layer 104, the characteristics of which may be specifically prepared in terms of layer thickness, material composition and the like, as required for the various types of transistors to be formed in the semiconductor device 100. In other cases, when an SOI architecture is not desired, the substrate 101 may be initially provided and the semiconductor layer 104 in its initial form may be formed by epitaxial growth and the like. Prior to or after incorporating a desired dopant species in respective areas of the substrate material 101, for instance, by ion implantation and the like, the isolation structure 103 may be formed on the basis of well-established lithography, etch, deposition and/or oxidation techniques, followed by respective planarization processes. If required, anneal processes may also be applied so as to activate dopant species and reduce implantation-induced damage. Thereafter, the dielectric layer 131 may be formed, for instance, by oxidation and/or deposition, wherein, when oxidation may be applied, the layer 131 may be formed on exposed surface areas of the semiconductor layer 104 only, while the isolation structure 103 may substantially not receive the layer 131. When forming the layer 131 mainly by deposition, the layer 131 may be formed on any exposed surface area. Thereafter, the high-k dielectric material 132 may be formed on the basis of well-established deposition techniques, such as chemical vapor deposition (CVD), atomic layer deposition (ALD) and the like. Typically, the thickness of the high-k dielectric material 132 may be significantly higher compared to the thickness of the dielectric layer 131 formed of a standard dielectric material. It should be appreciated that, if required, any further processes, such as anneal processes and the like, based on an appropriate gaseous ambient, may be applied in order to adjust the characteristics, in particular, of the high-k dielectric material 132 in accordance with device requirements.

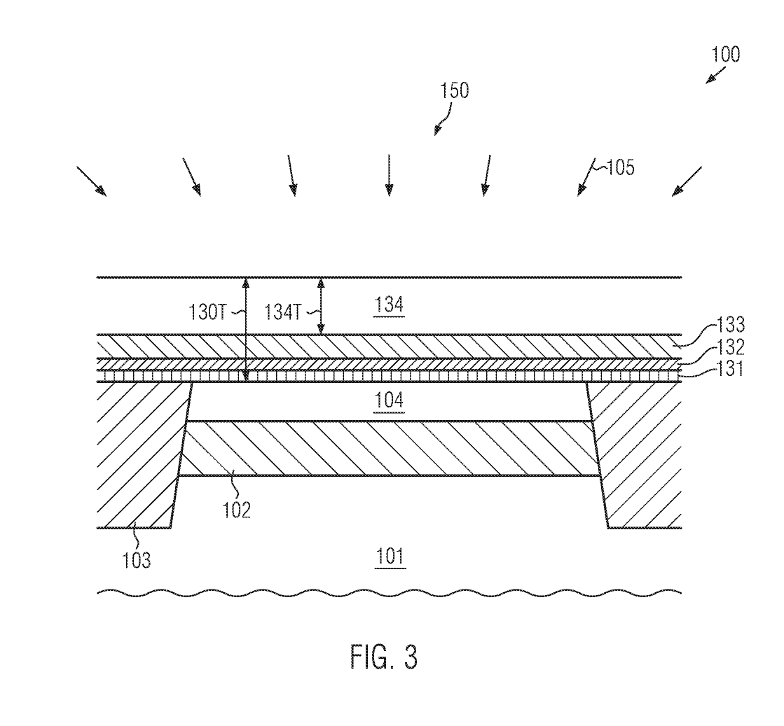

FIG. 2 schematically illustrates the semiconductor device 100 in a further advanced manufacturing stage, in which a material system 133, as part of the gate electrode material of a gate electrode structure still to be formed, may be provided above the gate dielectric material provided in the form of the layers 131 and 132. To this end, the material system 133 may typically comprise two or more different material layers (not shown) so as to adjust basic transistor characteristics, such as threshold voltage and the like, and to also provide superior conductivity of a gate electrode material positioned in the immediate vicinity of the gate dielectric materials 131, 132. To this end, well-established deposition techniques, such as CVD, ALD and the like, may be applied for forming, for instance, a titanium nitride layer, followed by the deposition of an appropriate work function metal, such as aluminum and the like, followed by a further barrier layer, such as titanium nitride and the like. It should be appreciated that a corresponding deposition sequence may also include a patterning process, since, typically, different material systems may be required for the different types of transistors to be formed in the semiconductor device 100. In some illustrative embodiments, these well-established process strategies may also be applied for providing the material system 133 for any type of transistor element to be formed in the semiconductor device 100. Consequently, up to this manufacturing stage of the semiconductor device 100, a high degree of compatibility may be achieved with respect to well-established conventional process strategies.

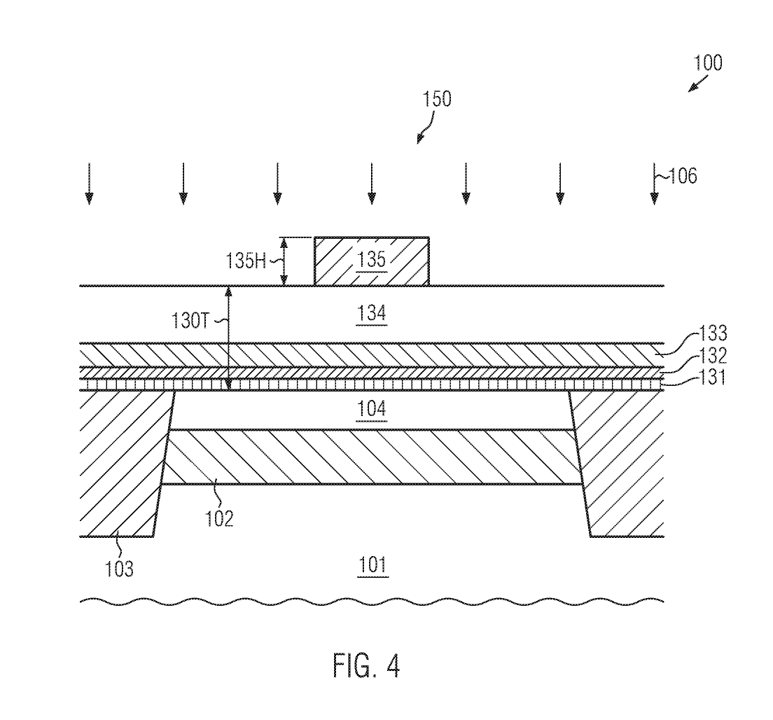

FIG. 3 schematically illustrates the semiconductor device 100 in a further advanced manufacturing stage. As illustrated, a metal-containing electrode material 134 is formed as a layer above the material system 133 with appropriate material composition and layer thickness 134T. In some illustrative embodiments, the electrode material 134 may be provided in the form of a metal with moderately low resistance, wherein the layer thickness 134T is adjusted to the overall requirements with respect to line resistance of the gate electrode structure still to be formed at a reduced overall height of the gate electrode structure, as already discussed above. In some illustrative embodiments, the electrode material 134 may represent a metal in the form of tungsten, while, in other cases, zirconium, hafnium, nickel, titanium and the like, or any combination thereof, may be used. The electrode material 134 may be formed with a thickness of approximately 20 nm and less, such as, for example, approximately 15 nm or less, wherein, in some cases, an entire height 130T of the gate electrode structure still to be patterned may be approximately 20 nm and less, such as 15 nm and less. The electrode material 134 may be deposited on the basis of any appropriate deposition technique, such as physical vapor deposition (PVD), ALD, metal organic CVD and the like. Furthermore, a post-deposition treatment may be applied in order to adjust the overall material characteristics.

In one illustrative embodiment, an anneal process 105 may be applied in an ambient established on the basis of forming gas, i.e., a mixture of hydrogen and nitrogen gases, thereby establishing superior material characteristics during the further processing of the semiconductor device 100. For example, the anneal process 105 may result in a reduction of metal oxide that may be present in and on the surface of the electrode material 134, thereby avoiding subsequent stress-related defect formation in the gate layer stack. A temperature range for the anneal process 105 may be approximately 300-700° C. or even higher. It should be appreciated that respective process parameters for the anneal process 105 may be readily established by performing respective experiments and by monitoring any gate layer stack failures in relation to the respectively selected process parameters.

As discussed above, in conventional sophisticated process strategies, the gate electrode material may be formed by, for instance, providing the material system 133, followed by the deposition of a semiconductor material, such as amorphous silicon, amorphous silicon/germanium and the like, with appropriate thickness that is significantly higher compared to the thickness 134T in order to obtain an appropriate required low overall gate resistance. Consequently, the respective deposition of the respective semiconductor material, the subsequent implantation of an appropriate dopant species and the following anneal process for recrystallizing a previously deposited semiconductor material, may be replaced by the deposition of the electrode material 134, possibly in combination with the anneal process 105, if required. Consequently, compared to the conventional processing, a reduction of overall process complexity may be achieved, while the height of the entire gate stack 130T may be significantly less compared to a corresponding gate layer stack of the conventional process strategy.

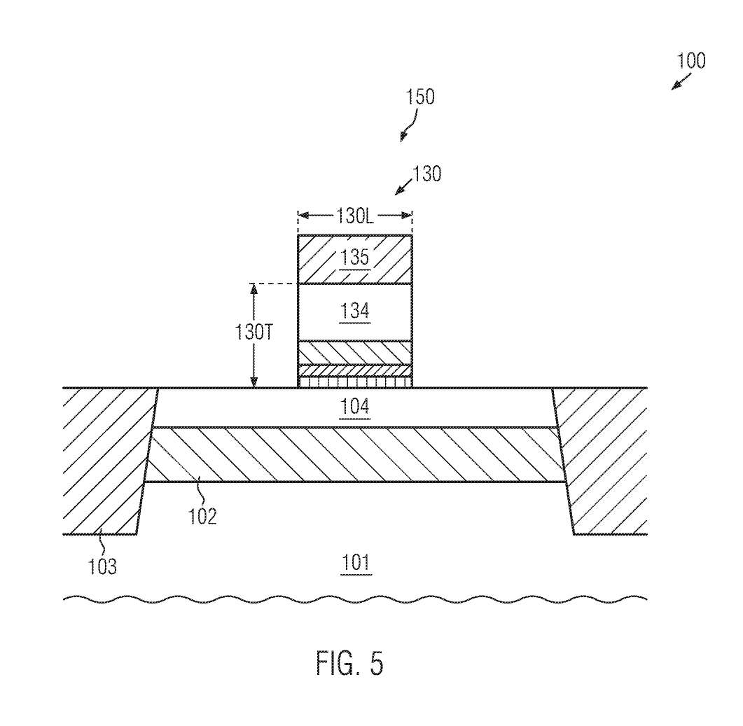

FIG. 4 schematically illustrates a cross-sectional view of the semiconductor device 100 in a further advanced manufacturing stage. As illustrated, a cap material 135, for instance, including silicon nitride, silicon dioxide and the like, may be formed above the electrode material 134 and may be patterned so as to correspond to the desired shape and length, i.e., in FIG. 4, the horizontal extension, of a gate electrode structure still to be formed. The cap material 135 may be formed by depositing any appropriate dielectric materials on the basis of well-established deposition techniques, such as CVD and the like, followed by sophisticated lithography processes and anisotropic etch techniques. In some illustrative embodiments, the cap material 135 may be provided with reduced height or thickness 135H compared to conventional strategies in which a gate layer stack of increased height based on a semiconductor material has to be patterned on the basis of the material 135. For instance, a moderate thickness of approximately 20 nm and even less may suffice for the cap material 135, wherein, however, if required, any other appropriate thickness or height 135H may be selected.

On the basis of the patterned cap material 135, a patterning process 106 may be performed so as to remove exposed portions of the material layers 134, 133, 132 and 131. The patterning process 106 may be performed on the basis of process parameters that may be obtained in relation to well-established etch recipes, which are typically applied when removing exposed portions of the material system 133, which includes metal species or metal layers. As previously discussed, in conventional strategies, the semiconductor material, such as a silicon material, must be initially patterned on the basis of well-established anisotropic etch techniques, followed by a further etch process based on etch parameters selected for etching through the material system 133, for instance, comprising titanium nitride, aluminum and the like. When establishing process parameters for the patterning process 106, similar process parameters may be initially selected so as to etch through the materials 134 and 133, wherein specific variations of process parameters for the material 134 may be readily determined on the basis of such experiments. For example, process parameters may be determined and selected for commonly etching through the materials 134, 133, while, in other cases, a first etch step may involve specifically designated process parameters for etching through the metal material 134, followed by a second etch step based on conventional well-established process parameters for etching through the material system 133. Consequently, compared to the conventional strategy requiring the patterning of two very different material systems, i.e., the semiconductor material and the material system 133, relatively similar process conditions may be selected for the process 106, wherein the reduced overall thickness 130T of the layer stack may also contribute to reduce overall process complexity.

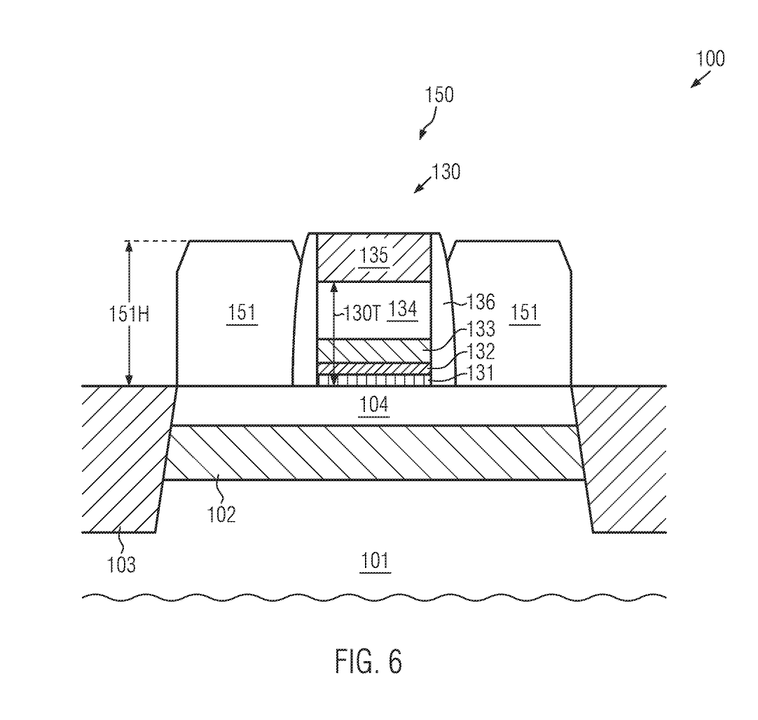

FIG. 5 schematically illustrates a cross-sectional view of the semiconductor device 100 after completing the above-described patterning process 106. That is, a gate electrode structure 130 may be provided so as to include the layers 131, 132, 133 and 134, wherein the layers 131 and 132 represent the gate dielectric material and the layers 133 and 134 represent the electrode material of the gate electrode structure 130. Furthermore, the cap material 135 may still be in place and may, according to some illustrative embodiments, be preserved throughout the entire process sequence, as will be described later on in more detail. Consequently, the gate electrode structure 130 may have the desired reduced height or thickness 130T and may have a gate length 130L that may comply with the overall device requirements and may, in some illustrative embodiments, be approximately 30 nm and significantly less, such as 28 nm, 22 nm, 12 nm and the like. It should be further appreciated that respective gate electrode structures 130 may also be formed on other device areas for other transistors, wherein a specific difference may possibly lie in the material system and in the dielectric layer 132 depending on the type of transistor to be formed.

On the basis of the device structure shown in FIG. 5, the further processing may be continued by encapsulating the gate electrode materials, in particular, the sensitive materials 133 and 132, in order to avoid significant modifications of these materials during any later processes, which may otherwise result in respective performance modifications. To this end, any well-established deposition technique may be applied, as may also be used during the processing of conventional gate electrode structures. Also in this case, the reduced overall height and, in particular, the reduced thickness 130T, may even provide relaxed process constraints, thereby ensuring a high degree of reliability of the respective encapsulation even if a further reduction of the gate length 130L is to be implemented. For example, a thin silicon nitride liner and the like (not shown) may be deposited on the basis of well-established techniques, followed by the deposition of one or more spacer layers, such as silicon nitride material, silicon dioxide and the like, in accordance with well-established strategies. Thereafter, the respective spacer layer or layers may be etched by anisotropic etch techniques for one type of transistors, while masking the respective material layer in transistors of a different type in which masking of any exposed semiconductor surface areas may be required during the further processing.

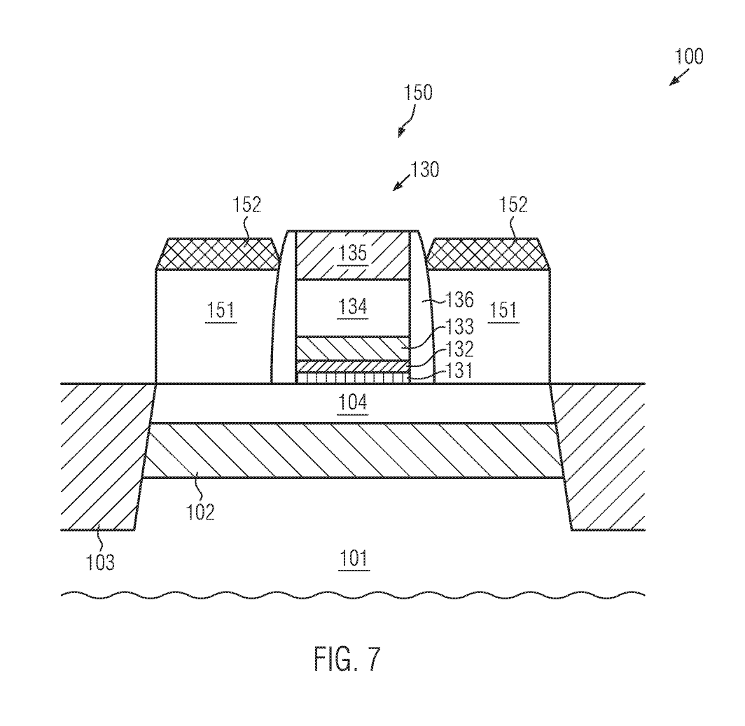

FIG. 6 schematically illustrates a cross-sectional view of the semiconductor device 100 in a further advanced manufacturing stage. As illustrated, the transistor 150 may comprise raised drain and source regions 151, which may be formed of highly doped crystalline semiconductor material, such as doped silicon/germanium material, silicon material, silicon/carbon material and the like. As illustrated, a respective height, indicated by 151H, of the raised drain and source regions may substantially correspond to the total height of the gate electrode structure 130 in this manufacturing stage, i.e., the thickness or height 130T of the actual gate electrode structure plus the thickness of the cap material 135. Consequently, in some illustrative embodiments, the height levels 130T and 151H may differ by approximately 15 nm to 25 nm, for instance, approximately 20 nm. Furthermore, the gate electrode structure may be encapsulated by any appropriate thin layer (not shown) and a sidewall spacer 136, for instance comprising silicon nitride, silicon dioxide and the like. The spacer 136 may be formed in accordance with process strategies as discussed above with reference to FIG. 5. Furthermore, the raised drain and source regions 151 may be formed on the basis of conventional process strategies in which exposed surface areas may be subjected to a respective cleaning process, while semiconductor areas of other transistors that may require a different type of semiconductor material in the respective raised drain and source areas may still be covered by a spacer layer, as discussed above. Thereafter, selective epitaxial growth techniques may be applied so as to grow the in situ doped semiconductor material of the raised drain and source regions 151 up to the required height 151H. Thereafter, the respective spacer layer (not shown) in other transistor areas may be etched into respective sidewall spacers, similar to the spacer 136, while the transistor 150 may be masked with a hard mask material, such as silicon nitride and a corresponding etch mask (not shown). Thereafter, other exposed surface areas may be subjected to the process sequence for forming the respective raised drain and source regions in order to grow the desired in situ doped semiconductor material, as discussed above.

It should be appreciated that, after forming the raised drain and source regions for the different types of transistors, in conventional approaches, the corresponding mask materials and, in particular, the cap material 135, may have to be removed on the basis of sophisticated wet chemical etch process and/or plasma-assisted etch processes, thereby also typically consuming a certain portion of the raised drain and source regions 151 and reducing the height thereof. In particular, the removal of the cap material 135 may, thus, contribute to a significant material loss in the raised drain and source regions 151. In the conventional strategy, removal of the cap material 135 may be necessary so as to expose the semiconductor material of the gate electrode structure in order to form therein a metal semiconductor compound in view of enhanced overall conductivity of the conventional gate electrode structure. Contrary to the conventional strategies, in some illustrative embodiments, the cap material 135 may be substantially preserved, thereby making a specific etch process for exposing an underlying gate electrode material obsolete.

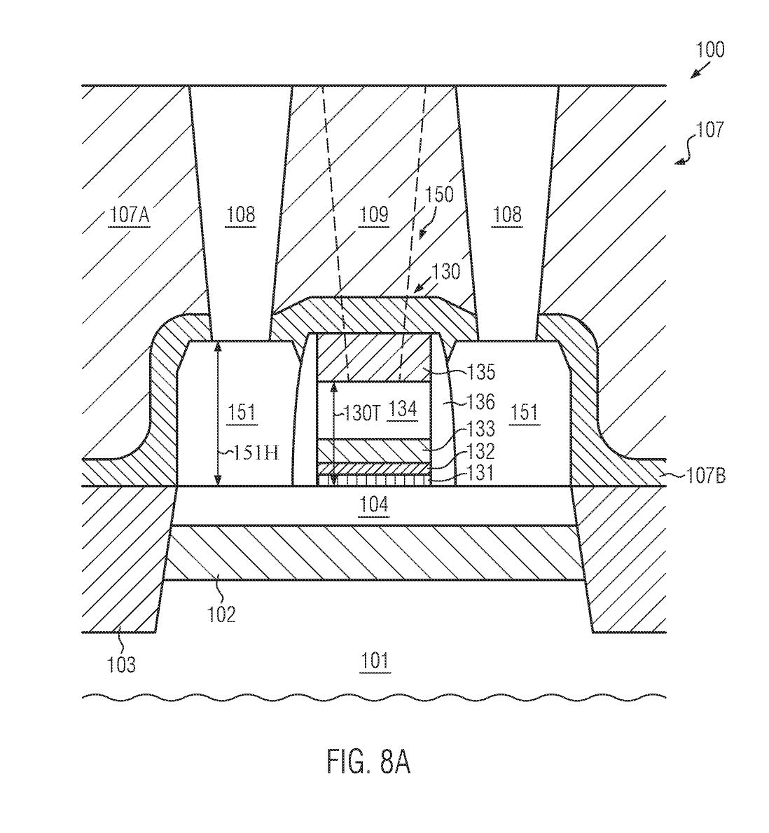

FIG. 7 schematically illustrates the semiconductor device 100 according to some illustrative embodiments, in which it is considered advantageous to provide a metal semiconductor compound 152, such as a nickel silicide material, in and on the raised drain and source regions 151. To this end, respective conventional process strategies may be applied, except for the challenging removal of the cap material 135, as discussed above, such as the deposition of respective spacer material, for instance, in the form of silicon dioxide and the like, and forming respective sidewall spacers (not shown) on exposed sidewall areas of the raised drain and source regions 151. Thereafter, the exposed top surface areas of the raised drain and source regions 151 may be prepared for the deposition of a metal material, such as nickel, platinum and the like, followed by one or more anneal processes in order to initiate a reaction between the semiconductor material of the regions 151 and the metal material. Thereafter, non-reacted metal material may be removed by well-established etch recipes, followed by a further anneal process, if required. Consequently, in the embodiment shown in FIG. 7, a high degree of device compatibility may be achieved, since the raised drain and source regions 151 may have a similar configuration as in conventional sophisticated transistor elements, wherein it should be noted that a corresponding material loss of the regions 151 typically associated with removal of the cap material 135 may be avoided.

In other illustrative embodiments, the formation of the metal semiconductor compound regions 152 may be omitted, thereby contributing even further to a significantly reduced overall process complexity, since the entire process module for forming the regions 152 may be omitted.

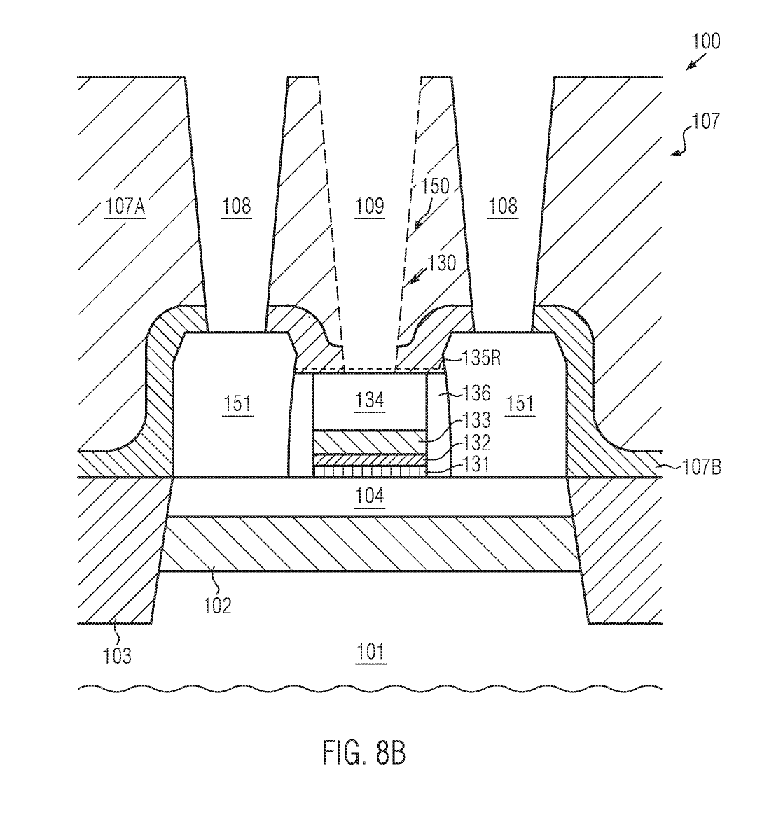

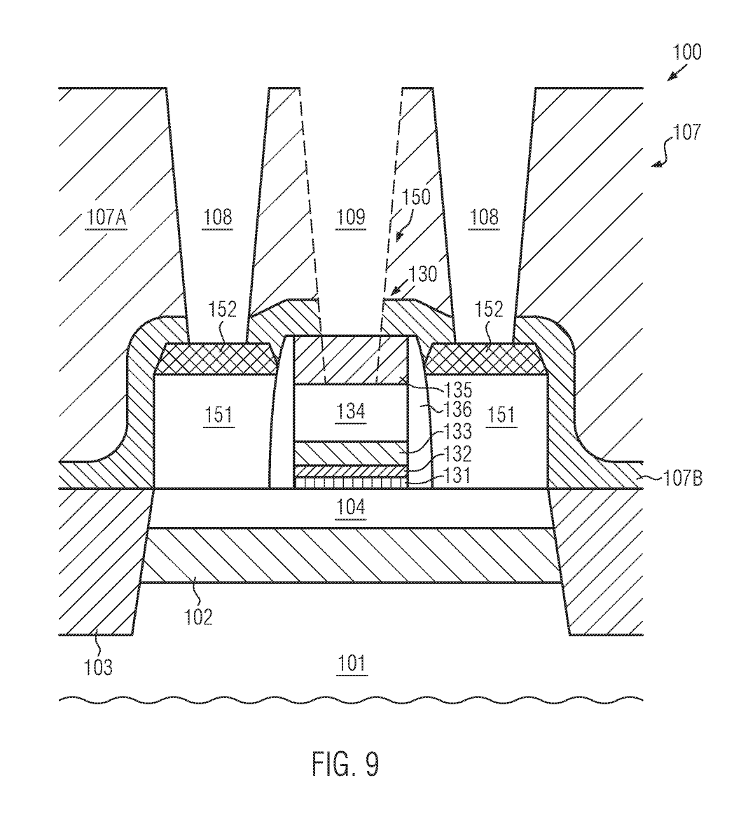

FIG. 8A schematically illustrates a cross-sectional view of the semiconductor device 100 in a further advanced manufacturing stage according to illustrative embodiments of the present disclosure. As illustrated, the semiconductor device 100 may comprise the transistor 150 including the raised drain and source regions 151, in which highly conductive semiconductor metal compound regions, such as the regions 152 (see FIG. 7), have not been formed. Moreover, a contact level 107 comprising two or more dielectric materials, such as materials 107B, 107A, in the form of, for instance, silicon nitride, silicon dioxide and the like, may be formed so as to encapsulate and, thus, passivate, the transistor element 150. In the illustrative embodiment shown in FIG. 8A, the gate electrode structure 130 may still be covered by the cap material 135 substantially without any material removal, except for any material loss experienced during respective removal and cleaning processes required during the previous processing, so that the transistor configuration as shown in FIG. 8A may be obtained on the basis of an overall process flow with significantly reduced complexity compared to conventional strategies. Furthermore, in this manufacturing stage, contact openings 108 extending to the raised drain and source regions 151 may be provided in the dielectric materials 107A, 107B, while, in this manufacturing stage or in a later manufacturing stage, a contact opening 109 may also be formed so as to extend to the electrode material 134 of the gate electrode structure 130. It should be appreciated that the contact opening 109 is typically formed at a different lateral position along the transistor width direction, i.e., the direction perpendicular to the drawing plane of FIG. 8A, compared to the contact openings 108 that connect to the drain and source regions 151.

In some illustrative embodiments, the semiconductor device 100 as shown in FIG. 8A may be formed on the basis of the following processes. The dielectric materials 107B, 107A may be deposited on the basis of well-established deposition techniques, such as plasma-enhanced CVD, thermally induced CVD and the like, followed by a respective planarization process in order to provide a substantially planar surface typography for the subsequent patterning process for forming the contact openings 108. To this end, sophisticated lithography techniques may be applied in order to form a corresponding etch mask for defining the openings 108 and possibly, in some illustrative embodiments, the opening 109, depending on the overall process requirements. Thereafter, a respective anisotropic etch recipe may be applied so as to initially etch through the material 107A using the layer 107B as an etch stop layer, followed by a further etch process to etch through the layer 107B, thereby finally exposing a surface portion of the drain and source regions 151.

As already discussed above, the process of defining the lateral position of the contact openings 108 is generally a challenging task, particularly with respect to ever-decreasing length dimensions, since respective overlay errors during the lithography sequence may result in a certain misalignment of the contact openings 108 so that, for instance, a certain overlap of the opening 108 with the drain or source region 151 and the gate electrode structure 130 may, in conventional approaches, result in unreliable contacts or even a short circuit between drain or source regions and the gate electrode structure. According to some illustrative embodiments, the significant difference in height level, i.e., the thickness 130T of the actual gate electrode structure 130 and the height or thickness 151H of the raised drain and source regions, may result in increased process robustness, since, for example, when etching through the material 107B in a final phase of the patterning process for the contact opening 108, there is still sufficient material of the cap material 135 available for still reliably covering the electrode material 134, even if the contact opening 108 overlaps with a part of the gate electrode structure 130. Therefore, in some illustrative embodiments, the contact opening 109 for connecting to the electrode material 134 may be performed in a separate etch step prior to or after forming the contact openings 108, thereby insuring a high degree of process robustness, as discussed above. It should be appreciated that proper alignment of the contact opening 109 for the gate electrode structure 130 is less demanding, since this contact opening may be typically formed above the isolation structure and may be offset from the respective drain and source regions 151. Consequently, on the basis of the strategy described with reference to FIG. 8A, a further reduction of the transistor length may be readily implemented without contributing to increased contact failures.

FIG. 8B schematically illustrates the semiconductor device 100 according to further illustrative embodiments. As illustrated, the gate electrode structure 130 may comprise the cap material in a significantly reduced amount, as indicated by 135R, or the cap material 135 (see FIG. 8A) may be substantially completely removed prior to forming the dielectric materials of the contact level 107. To this end, similar process techniques may be applied as in the conventional strategies, wherein, as previously discussed, a relatively thin initial thickness of the cap material may also significantly relax the problem of undue material loss of the drain and source regions 151. During the formation of the contact openings 108, 109, a common patterning sequence may be applied, for instance, by initially etching through the material 107A, while using the material 107B as etch stop material, and subsequently etching through the material 107B, thereby landing on the raised drain and source regions 151 for the contact openings 108 on the one hand, and landing on and in the electrode material 134 for the contact opening 109 on the other hand. Consequently, in this manner, well-established patterning regimes may also be applied to the semiconductor device 100, thereby providing a high degree of process compatibility.

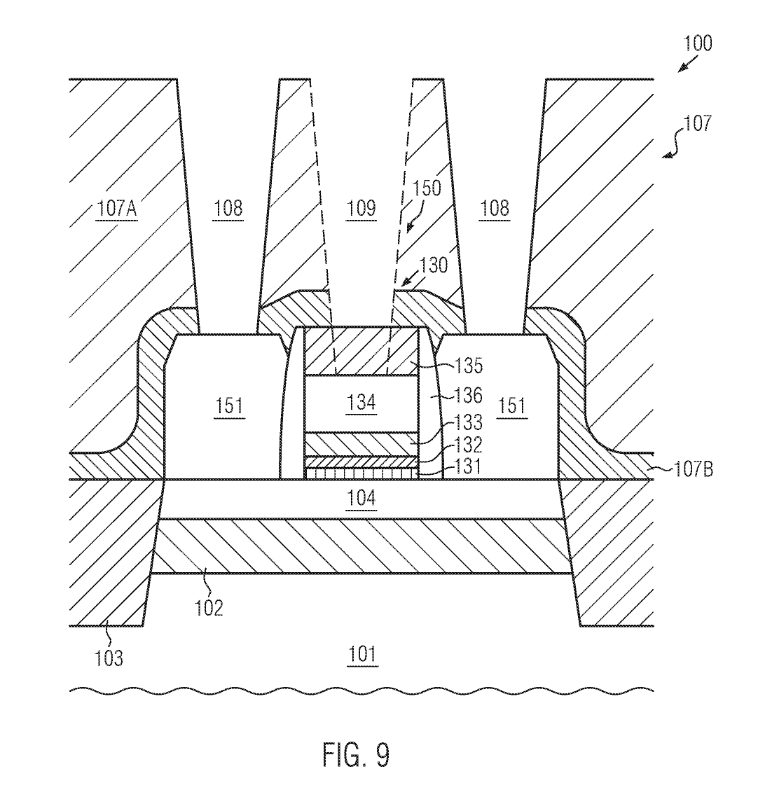

FIG. 9 schematically illustrates the semiconductor device 100 in a cross-sectional view in an advanced manufacturing stage according to a further illustrative embodiment, wherein the device configuration as shown in FIG. 9 may be obtained when starting from the device 100 as shown in FIG. 7. That is, based on a configuration with the gate electrode structure 130 still including the cap material 135 and with the metal semiconductor compound regions 152 formed in the drain and source regions 151, the contact level 107 may be formed in a configuration and in accordance with process strategies as already discussed above with reference to FIGS. 8A, 8B. That is, the contact openings 108 may be formed in the dielectric materials 107A, 107B on the basis of patterning strategies that provide superior process robustness with respect to overlay errors and the like, as already discussed above. That is, even for a significant misalignment of the contact openings 108, a respective contact failure due to short circuits, unreliable contact formation and the like may be significantly reduced. Similarly, in a second patterning sequence, the contact opening 109 connecting to the electrode material 134 may be formed, as discussed above. Consequently, in this illustrative embodiment, high process robustness with respect to the formation of the contact openings 108 may be ensured, while a high degree of compatibility with a conventional device configuration in terms of the drain and source regions 151 may be preserved. That is, if the metal semiconductor compound regions 152 extending along the entire width and length of the surface of the raised drain and source regions 151 are considered advantageous, this concept may be preserved, even for further device scaling due to the superior process robustness for forming the contact openings 108.

It should be appreciated that, in other illustrative embodiments, as discussed above with reference to FIG. 8B, the contact opening 109 may be formed together with the contact openings 108 in the same patterning sequence by appropriately thinning or removing the cap material 135 if overlay robustness is of less relevance. Consequently, in this case, as already discussed above with reference to FIG. 8B, conventional patterning regimes with reduced complexity may be applied for forming the contact openings 108, 109 during a common patterning sequence.

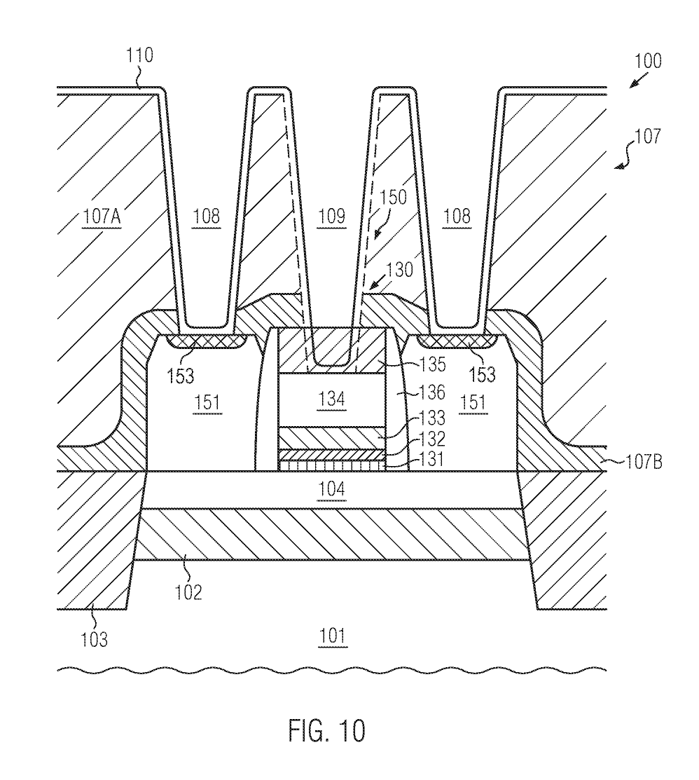

FIG. 10 schematically illustrates a cross-sectional view of the semiconductor device 100 in a further advanced manufacturing stage. As shown, a respective metal-containing material layer 110 may be formed at least within the contact openings 108, 109 in order to prepare the openings for the deposition of a further highly conductive material, such as tungsten and the like. Frequently, the layer 110 may comprise titanium, which may be deposited on the basis of any appropriate deposition technique, such as CVD, PVD and the like. Thereafter, the semiconductor device 100 may be annealed in the presence of a silicon-containing ambient and/or a respective silicon layer may be deposited prior to the anneal process, thereby converting the titanium into a titanium silicide material, which may act as a conductive and efficient barrier material for the subsequent metal to be formed in the contact openings 108, 109. During the respective process sequence, titanium silicide may also form in surface areas of the drain and source regions 151, which are exposed by the contact openings 108. Hence, respective semiconductor metal compound regions 153 may be locally formed within and around the contact openings 108. Thus, also in this case, a significantly reduced contact resistance to the raised drain and source regions 151 may be obtained. On the other hand, the entire process module for forming the metal semiconductor compound regions 152 (see FIG. 7) may be omitted, thereby also contributing to an overall reduced complexity of the entire process flow, without substantially affecting overall contact resistance of the drain and source regions 151.

As a result, the present disclosure provides semiconductor devices including transistor elements having a gate electrode structure with reduced height of the electrode materials, thereby contributing to a reduced parasitic capacitance between the raised drain and source regions and the gate electrode structure. To this end, a highly conductive metal material may be deposited in an early manufacturing stage, i.e., prior to actually patterning the gate electrode structure so as to obtain a significantly reduced overall thickness of the resulting gate layer stack. Moreover, compared to conventional gate formation strategies requiring the deposition, implantation and annealing of a semiconductor-based electrode material, a reduced process complexity may be obtained during the formation of the deposition of the gate layer stack. Furthermore, the patterning of the resulting gate layer stack may be simplified due to the reduced overall thickness and due to the similarity of the gate electrode materials compared to conventional strategies requiring the patterning of a relatively thick semiconductor material followed by the material system including metal species as required for sophisticated high-k dielectric gate electrode structures.

Moreover, in some illustrative embodiments, a significant reduction in complexity may be achieved by omitting the formation of any semiconductor metal compound in the raised drain and source regions, while, in other cases, respective metal semiconductor compound regions may still be formed, if considered appropriate. Furthermore, in some illustrative embodiments, significant enhanced process robustness upon forming respective contact elements may be achieved, since overlay errors and the resulting misalignment of contact openings connecting to the drain and source regions may not result in respective contact failures. In other cases, a high degree of process compatibility with conventional strategies may be preserved upon forming the contact openings for the drain and source regions and the gate electrode structure in a common patterning sequence while requiring only a respective material removal of the cap material of the gate electrode structure. Consequently, irrespective of the process sequence for forming the contact elements, and irrespective of whether or not metal semiconductor compound regions may be provided in the raised drain and source regions, a significantly reduced parasitic capacitance between the drain and source regions and the gate electrode may be achieved due to the very different height levels thereof, while a reduced process complexity may still be achieved during the formation of the gate electrode structure. Therefore, the present disclosure is highly advantageous for applications requiring superior transistor performance in view of parasitic capacitances of the gate electrode structures, for instance, for RF applications and the like, and may also provide enhanced process robustness upon further device scaling.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Note that the use of terms, such as “first,” “second,” “third” or “fourth” to describe various processes or structures in this specification and in the attached claims is only used as a short-hand reference to such steps/structures and does not necessarily imply that such steps/structures are performed/formed in that ordered sequence. Of course, depending upon the exact claim language, an ordered sequence of such processes may or may not be required. Accordingly, the protection sought herein is as set forth in the claims below.

1. A method, comprising:
forming a metal-containing layer as a top electrode material of a gate electrode structure of a transistor element, said top electrode material being formed so as to extend to a first height level above an active semiconductor layer of said transistor element;
forming a gate cap material above said top electrode material of said gate electrode structure, said gate cap material being formed so as to extend to a second height level above said active semiconductor layer; and
after forming said top electrode material, forming raised drain and source regions of said transistor element in the presence of said gate cap material, said raised drain and source regions being formed to extend to a third height level above said active semiconductor layer that is greater than said first height level, wherein said second height level is substantially equal to or greater than said third height level.

2. (canceled)

3. The method of claim 1, wherein said first height level is approximately 20 nm or less.

4. The method of claim 1, wherein forming said gate cap material comprises forming a layer of said gate cap material above a layer of said top electrode material, patterning said layer of gate cap material so as to form a patterned gate cap material, and wherein forming said top electrode material comprises patterning a layer of top electrode material by using said patterned gate cap material as a mask.

5. The method of claim 4, further comprising forming a sidewall spacer on sidewalls of said top electrode material prior to forming said raised drain and source regions.

6. The method of claim 4, further comprising forming a dielectric layer above said transistor element and forming a first contact opening in the presence of said gate cap material in a first patterning sequence and forming second contact openings in a second patterning sequence, wherein said first contact opening extends to said top electrode material and said second contact openings extend to said raised drain and source regions.

7. The method of claim 4, further comprising removing at least a portion of said gate cap material after forming said raised drain and source regions.

8. The method of claim 7, further comprising forming a metal semiconductor compound in said raised drain and source regions prior to removing said at least a portion of said gate cap material.

9. The method of claim 1, further comprising forming a dielectric layer above said transistor element and forming contact openings that expose a crystalline semiconductor material of said raised drain and source regions.

10. The method of claim 9, further comprising forming a metal semiconductor compound on said exposed crystalline semiconductor material.

11. The method of claim 1, wherein said top electrode material comprises tungsten.

12. A method of forming a transistor element, said method comprising:
forming one or more metal-containing material layers above a gate dielectric layer, said one or more metal-containing material layers forming an electrode material of a gate electrode structure, said electrode material extending to a first height level above an active semiconductor layer of said transistor element;
forming a gate cap material above said electrode material of said gate electrode structure, said gate cap material being formed so as to extend to a second height level above said active semiconductor layer; and
forming raised drain and source regions in the presence of said gate cap material so as to extend to a third height level above said active semiconductor layer that is greater than said first height level, wherein said second height level is substantially equal to or greater than said third height level.

13. The method of claim 12, wherein said first height level is approximately 20 nm or less.

14. The method of claim 12, wherein said raised drain and source regions are formed after forming said one or more metal-containing material layers.

15. The method of claim 12, further comprising:
forming a first contact opening in a dielectric layer formed above said transistor element, wherein said first contact opening extends to said one or more metal-containing material layers of said electrode material; and
forming a first contact element in said first contact opening.

16. The method of claim 15, further comprising:
forming a plurality of second contact openings in said dielectric layer so as to expose a crystalline semiconductor material of said drain and source regions; and
forming a second contact element in each of said plurality of second contact openings.

17. The method of claim 16, wherein said first contact openings and said second contact openings are formed in separate patterning sequences.

18. The method of claim 12, further comprising forming a metal semiconductor compound in said drain and source regions while masking said electrode material with a dielectric cap layer.

19.-20. (canceled)

21. A method, comprising:
forming a gate layer stack above an active semiconductor layer, wherein forming said gate layer stack comprises:
forming a first material layer system comprising one or more gate dielectric material layers above said active semiconductor layer;
forming a second material layer system comprising one or more work function material layers above said first material layer system; and
forming a third material layer system comprising one or more metal-containing material layers above said second material layer system, wherein an upper surface of said third material layer system extends to a first height level above said active semiconductor layer;
forming a patterned gate cap material layer above said gate layer stack, wherein an upper surface of said patterned gate cap layer extends to a second height layer above said active semiconductor layer;
patterning said gate layer stack to form a gate electrode structure above said active semiconductor layer by using said patterned gate cap layer as a patterning mask; and
forming raised drain and source regions adjacent to opposing sides of said gate electrode structure in the presence of said patterned gate cap layer, wherein an upper surface of said raised drain and source regions extends to a third height level above said active semiconductor layer that is greater than said first height level, and wherein said second height level is greater than or equal to said third height level.

22. The method of claim 21, further comprising:
forming a dielectric layer above said transistor element;
forming a first contact opening in a first patterning sequence, said first contact opening extending to said third material layer system of said gate electrode structure; and
forming second contact openings in a second patterning sequence, said second contact openings extending to said raised drain and source regions.
